(19) United States
(12) Patent Application Publication
(10) Pub. No.: US 2018/0286643 A1
(43) Pub. Date: Oct. 4, 2018

(54) ADVANCED OPTICAL SENSOR, SYSTEM, AND METHODOLOGIES FOR ETCH PROCESSING MONITORING

(71) Applicant: Tokyo Electron Limited, Minato-ku (JP)

(72) Inventors: Holger TUITJE, Fremont, CA (US); Xinkang Tian, Fremont, CA (US); Ching-Ling Meng, Sunnyvale, CA (US); Vi Vuong, Fremont, CA (US); Wen Jin, Fremont, CA (US); Zheng Yan, San Jose, CA (US); Mihail Mihaylov, San Jose, CA (US)

(73) Assignee: Tokyo Electron Limited, Minato-ku (JP)

(21) Appl. No.: 15/472,494

(22) Filed: Mar. 29, 2017

(51) Int. Cl. H01J 37/32; H01L 21/67; H01L 21/3065; H01L 21/66; G01N 21/31; G06N 99/00

(52) U.S. Cl. CPC H01J 37/32972; H01L 21/67069; H01L 21/67253; H01L 21/3065; G01N 2201/061; G01N 21/31; G06N 99/005; H01J 2237/334; H01L 22/26

(57) ABSTRACT

An apparatus, system, and method for in-situ etching monitoring in a plasma processing chamber. The apparatus includes a continuous wave broadband light source; an illumination system configured to illuminate an area on a substrate with an incident light beam having a fixed polarization direction, the incident light beam from the broadband light source being modulated by a shutter; a collection system configured to collect a reflected light beam being reflected from the illuminated area on the substrate, and direct the reflected light beam to a detector; and processing circuitry. The processing circuitry is configured to process the reflected light beam to suppress background light, determine a property value from the processed light, and control an etch process based on the determined property value.

### BACKGROUND

The present disclosure relates to in-situ etch process monitoring, and, more particularly, to methods, systems, and apparatuses for real-time in-situ film properties monitoring of the plasma etch process.

Plasma etch processes are commonly used in conjunction with photolithography in the process of manufacturing semiconductor devices, liquid crystal displays (LCDs), light-emitting diodes (LEDs), and some photovoltaics (PVs).

In many types of devices, such as semiconductor devices, a plasma etch process is performed in a top material layer overlying a second material layer, and it is important that the etch process be stopped accurately once the etch process has formed an opening or pattern in the top material layer, without continuing to etch the underlying second material layer. The duration of the etch process has to be controlled accurately so as to either achieve a precise etch stop at the top of an underlying material, or to achieve an exact vertical dimension of etched features.

For purposes of controlling the etch process various methods are utilized, some of which rely on analyzing the chemistry of a gas in a plasma processing chamber in order to deduce whether the etch process has progressed, for example, to an underlying material layer of a different chemical composition than the material of the layer being etched.

Alternatively, in-situ metrology devices (optical sensors) can be used to directly measure the etched top layer during the etch process and provide feedback control for accurately stopping the etch process once a certain vertical feature has been attained. For example, in a generic spacer application the goal for an in-situ optical sensor for film thickness monitoring is to stop anisotropic oxide-etch at a few nm before touchdown (soft landing), then switch to isotropic etching to achieve an ideal spacer profile. Further, the in-situ metrology devices may be used for real-time actual measurement of the films and etch features during the etch process to determine information about the sizes of structures which can be used to control the etch process and/or to control subsequent processes (e.g., a process to compensate for a certain out-of-specification dimension).

The foregoing “Background” description is for the purpose of generally presenting the context of the disclosure. Work of the inventor, to the extent it is described in this background section, as well as aspects of the description which may not otherwise qualify as prior art at the time of filing, are neither expressly or impliedly admitted as prior art against the present invention.

### SUMMARY

An aspect of the present disclosure includes an apparatus for in-situ etching monitoring in a plasma processing chamber. The apparatus includes a continuous wave broadband light source; an illumination system configured to illuminate an area on a substrate with an incident light beam having a fixed polarization direction, the incident light beam from the broadband light source being modulated by a shutter; a collection system configured to collect a reflected light beam being reflected from the illuminated area on the substrate, and direct the reflected light beam to a detector; and processing circuitry. The processing circuitry is configured to process the reflected light beam to suppress background light, determine a property value from the processed light, and control an etch process based on the determined property value.

Another aspect of the present disclosure includes a plasma processing system. The system includes a plasma processing chamber and an oblique incidence reflectometer. The oblique incidence reflectometer includes a continuous wave broadband light source, a detector, an illumination system configured to illuminate an area on a substrate deposited in the plasma processing chamber with an incident light beam having a fixed polarization direction, the incident light beam from the broadband light source being modulated by a shutter, a collection system configured to collect a reflected light beam being reflected from the illuminated area on the substrate, and direct the reflected light beam to the detector, and processing circuitry. The processing circuitry is configured to process the reflected light beam to suppress background light, determine a property value from the processed light, and control an etch process based from the determined property value.

Another aspect of the present disclosure includes a method for in-situ etching monitoring. The method includes acquiring a background corrected spectrum associated with a reflected light beam during an etch process, the reflected light beam being formed from the reflection of a modulated incident light beam having a fixed polarization direction from an area of a substrate deposited in a plasma processing chamber, the incident light beam being from a broadband light source being modulated using a shutter; determining a property value associated with the background corrected spectrum using a training model; and controlling the etch process based on the determined property value.

The foregoing paragraphs have been provided by way of general introduction, and are not intended to limit the scope of the following claims. The described embodiments, together with further advantages, will be best understood by reference to the following detailed description taken in conjunction with the accompanying drawings.

### BRIEF DESCRIPTION OF THE DRAWINGS

A more complete appreciation of the disclosure and many of the attendant advantages thereof will be readily obtained as the same becomes better understood by reference to the following detailed description when considered in connection with the accompanying drawings, wherein:

FIG. 1 is a schematic diagram of a system for etch process monitoring according to one example;

FIG. 2 is a schematic view of an optical sensor according to one example;

FIG. 3 is a schematic view of an optical sensor according to one example;

FIG. 4A is a schematic of an exemplary configuration to obtain a reference beam according to one example;

FIG. 4B is a schematic of an exemplary configuration to obtain a reference beam according to one example;

FIG. 5A is a block diagram of an optical modulation/shutter module according to one example;

FIG. 5B is a schematic that shows a timing diagram of a shutter according to one example;

FIG. 6 is a schematic that shows exemplary configurations of the optical sensor;

FIG. 7 is a schematic that shows a plasma processing chamber equipped with an optical sensor according to one example;

FIG. 8 is a flowchart that shows a method for in-situ monitoring of an etch process according to one example;

FIG. 9 is a schematic that shows exemplary results; and

FIG. 10 is an exemplary block diagram of a controller according to one example.

### DETAILED DESCRIPTION

Referring now to the drawings, wherein like reference numerals designate identical or corresponding parts throughout several views, the following description relates to a system and associated methodology for real-time in-situ film properties monitoring of a plasma process of patterned or un-patterned wafer in semiconductor manufacturing.

Reference throughout the specification to “one embodiment” or “an embodiment” means that a particular feature, structure, material, or characteristic described in connection with the embodiment is included in at least one embodiment, but do not denote that they are present in every embodiment. Thus, the appearances of the phrases “in one embodiment” in various places through the specification are not necessarily referring to the same embodiment. Furthermore, the particular features, structures, materials, or characteristics may be combined in any suitable manner in one or more embodiments.

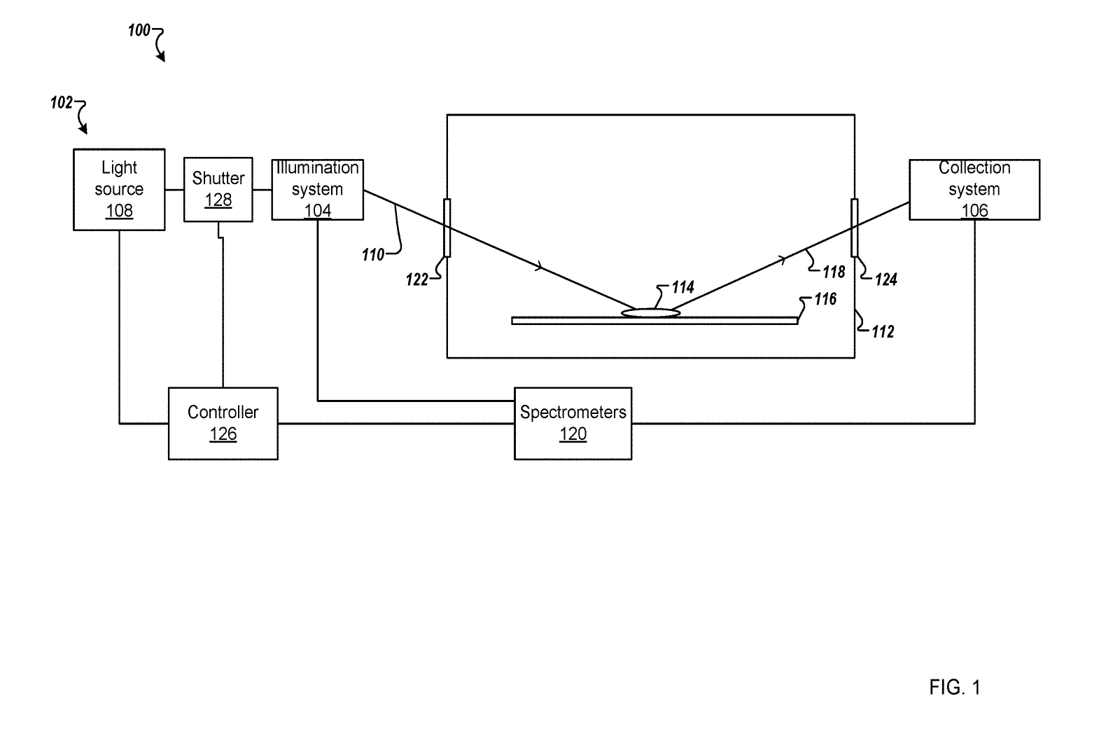

FIG. 1 is a side view schematic of a plasma processing system 100 equipped with an optical sensor 102 according to one example. The plasma processing system 100 includes a plasma processing chamber 112.

The optical sensor 102 may be an oblique incidence reflectometer that includes an illumination system 104 and a collection system 106. The optical sensor 102 is configured for measuring the reflected light from an illuminated area 114 on a substrate 116 during a plasma etching process in the plasma processing chamber 112. The illuminated area 114 may be adjustable as a function of the size of the substrate 116. The illumination system 104 and the collection system 106 may be located outside of the plasma processing chamber 112.

In the optical sensor 102, a light source 108 is used to form the incident light beam 110 for substrate illumination. In an embodiment, the light source 108 is a broadband light source such as continuous wave (CW) broadband light source, for example a laser driven plasma light source (LDLS) that provides light with very high brightness across a broad spectrum UV (ultraviolet)-Vis (visible)-NIR (near infrared) (i.e., 190 nm-2000 nm) with a long-life bulb (>9000 hours) such as EQ-99X LDLS™ from ENERGETIQ. The light source 108 may be fiber coupled to the illumination system 104 after being modulated by a shutter 128.

The light source 108 may or may not be mounted proximate to the plasma processing chamber 112 or any enclosure housing the optical sensor 102, and in the case of being mounted remotely, the incident light beam 110 can be fed into other components proximate to the plasma processing chamber 112 by an optical fiber, or by a set of optical components such as mirrors, prisms, and lenses as described later herein. The optical sensor 102 may also include relay optics and polarizers for the incident and reflected light beams. In one example, the relay optics use a reflective objective to minimize optical aberrations.

The incident light beam 110 is being reflected from the substrate 116 to form a reflected light beam 118. The optical sensor 102 also includes a detector such as spectrometers 120 (e.g., measurement spectrometer) for measuring the spectral intensity of the reflected light beam 118, for example, an ultra-broad band (UBB) spectrometer (i.e., 180 nm-1080 nm). The measurement spectrometer of spectrometers 120 may be fiber coupled to the collection system 106. The optical sensor 102 may also include one or more optical windows mounted on the wall of the plasma processing chamber 112. In one example, the optical sensor 102 may include two optical windows 122, 124 mounted on the wall of the plasma processing chamber 112 opposite of each other. A first window 122 transmits the incident light beam 110 and a second window 124 transmits the reflected light beam 118.

A percentage of the incident light beam 110 is directed to a reference channel of spectrometers 120 (i.e., reference spectrometer). Its purpose is to monitor the spectral intensity of the incident light beam 110 so any changes of the intensity of incident light beam 110 can be accounted for in the measurement process. Such changes of intensity may occur due to drifting output power of light source 108 for example. In one implementation, the intensity of a reference light beam may be measured by one or more photodiodes or the like. For example, a photodiode may detect the reference light beam and provide a reference signal that is proportional to the intensity of the incident light beam 110 which is integrated across the entire illumination spectrum (e.g., UV-VIS-NIR).

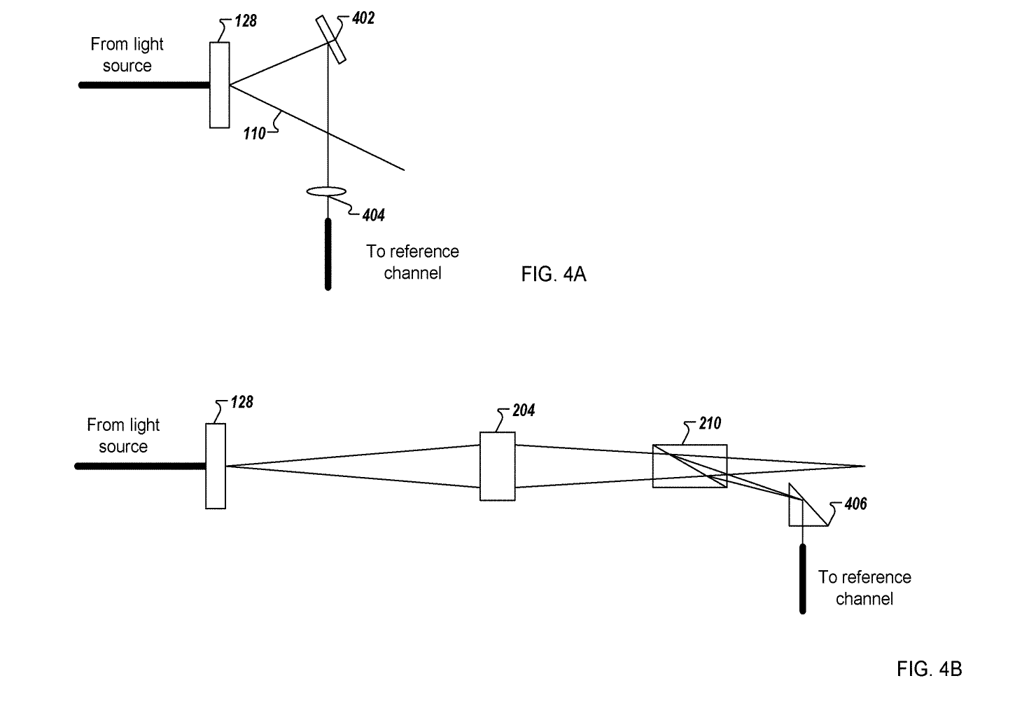

In one implementation, the intensity of the reference light beam may be measured using a set of photodiodes. For example, the set of photodiodes may include three photodiodes, spanning UV-VIS-NIR wavelength respectively. A filter may be installed in front of each photodiode of the set of photodiodes. For example, band pass filters may be used to monitor a portion of the spectrum (e.g., UV, VIS, NIR) for intensity variation of the light source 108. In one implementation, the reference light beam may be dispersed using a prism or a grating into the set of photodiodes. Spectrally-dependent intensity variation of the light source 108 may be tracked and corrected for without the use of a reference spectrometer. Exemplary configurations for obtaining a reference light beam are shown in FIGS. 4A and 4B discussed below.

The incident light beam 110 is modulated by a chopper wheel or shutter 128 in order to account for the light background (i.e., light which is not indicative of the reflected light of the incident light beam 110 such as plasma light emission or background light) measured by a measurement channel of spectrometers 120 when the incident light beam 110 is blocked.

The measured spectral intensity of the reflected light beam 118 and the measured spectral intensity of the reference light beam are provided to a controller 126 that process the measured spectral intensity of the reflected light beam 118 to suppress the light background and uses special algorithms such as machine learning methods to determine a layer of interest properties (e.g., feature dimension, optical properties) to control the plasma etching process as described further below.

The optical sensor 102 and associated methodologies can also use periodic measurements on a reference wafer (calibration), such as a bare silicon wafer, to compensate for optical sensor or etch chamber components drifts as described later herein.

The incident light beam 110 and the reflected light beam 118 are tilted with respect to the normal to the substrate 116, by an angle of incidence θ (AOI), which can vary from greater than zero to less than 90 degrees, or alternatively from greater than 30 degrees to less than 90 degrees, and preferably greater than 60 degrees to less than 90 degrees. A high angle of incidence (e.g., 85 degrees) may be preferable for a plasma processing chamber 112 having limited or no top access.

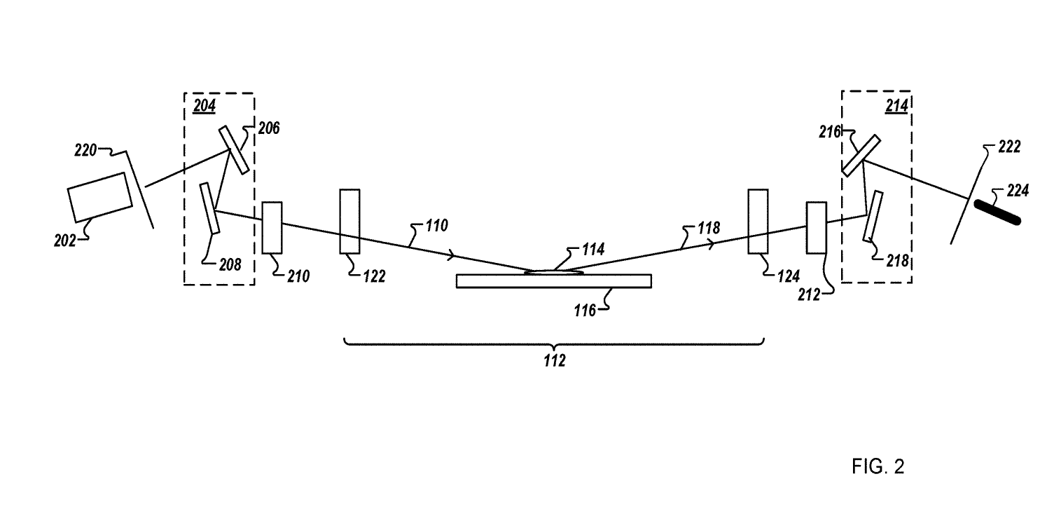

FIG. 2 is a schematic view of the optical sensor 102 according to one example. From light source 108, incident light beam 110 is passed to an illumination optics module 202 and a reflective objective 204 which forms the incident light beam 110 of an appropriate diameter and focus to achieve a certain illuminated area size 114 on the substrate 116. The illumination optics may include a pinhole 220 (e.g., 100 μm). The incident light beam 110 may also be passed through Neutral-density filters.

The size of the illuminated area 114 on substrate 116 can vary from 50 microns to 60 mm (millimeters) or more. Due to the circular beam cross section and very large angle of incidence, the illuminated area is elliptical (i.e., spot). The ratios of major and minor diameters of the ellipse are generally between 2 and 10, where higher values correspond with larger angles of incidence. The size of the illuminated area 114 may depend on the sizes and characteristics of the structures being measured on the substrate 116 and may be adjustable to ensure good signal and preferably 1 mm×10 mm, 2 mm×20 mm, 3 mm×30 mm, or 5 mm×58 mm for an angle of incidence of 85 degrees or 5 mm×11.5 mm, 6 mm×14 mm, 8 mm×18 mm for an angle of incidence of 64 degrees. The illuminated area 114 may cover multiple structures on the substrate 116. Thus, detected optical properties (e.g., index of refraction) may represent an average of the features associated with the structures of the substrate 116. The reflective objective 204 may include a concave mirror 206 and a convex mirror 208.

In an embodiment, the incident light beam 110 may be passed through an elliptical aperture, which results in a circular illuminated spot on the substrate 116. The elliptical aperture may be positioned in the incident light beam 110 path after pinhole 220. In some implementations, the elliptical aperture may be modified to generate an illuminated spot having different shapes (e.g., rectangular, square). Subtle modification to the elliptical aperture can be used to efficiently optimize the size and shape of the illuminated area on the substrate, for example based on the sizes and characteristics of the structures being measured.

In an embodiment, the incident light beam 110 is then passed through a polarizer 210, which imposes a linear polarization to the incident light beam 110 that reaches the substrate 116. The polarizer 210 may be a Rochon Polarizer with high extinction ratio, large e- and o-ray separation, for example, a MgF2 Rochon polarizer. Polarization of the incident light beam 110 increases the signal to noise ratio of the reflectometer signal, and thereby improves measurement accuracy and improves sensitivity to a feature dimension measurement compared to an un-polarized incident light beam.

After passing through the polarizer 210, the incident light beam 110 reaches the first optical window 122 mounted on the wall of plasma processing chamber 112. The first optical window 122 allows access for incident light beam 110 to the interior of the plasma processing chamber 112.

The second optical window 124 allows the passage of the reflected light beam 118 out of the plasma processing chamber 112, so its intensity can be measured. Depending on the configuration of plasma processing chamber 112, i.e. the type of plasma source being used, the windows 122, 124 may be quartz, fused silica, or sapphire depending on the application and how aggressive the chemistry of the plasma.

The reflected light beam 118 is passed through a second polarizer 212 to only allow p-polarized light reflected from the substrate 116 to be measured. After passing through the second polarizer 212, the reflected light beam 118 is passed through a second reflective objective 214. The second reflective objective 214 may be similar to the reflective objective 204. The second reflective objective 214 may include a concave mirror 216 and a convex mirror 218.

After passing through the second reflective objective 214, the reflected light beam 118 may be collected via an optical fiber and directed to a measurement channel of the spectrometer 120. The second reflective objective 214 may focus the reflected light beam 118 on a detector, for example, the optical fiber coupled to the measurement channel of the spectrometer 120. The reflected light beam 118 may be passed through a pinhole 222 positioned before the optical fiber 224 in the path of the reflected light beam 118.

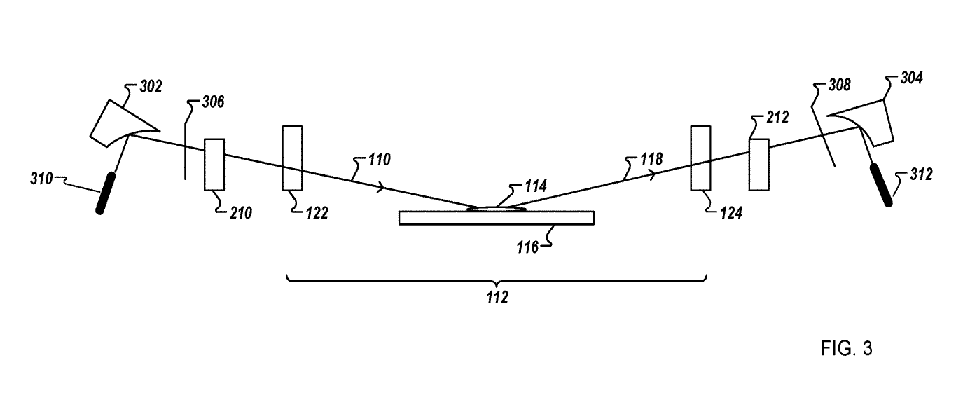

FIG. 3 is a schematic view of the optical sensor 102 according to one example. In one embodiment, the reflective objective 204 may include an off-axis parabolic mirror 302 in the illumination system 104 and a second off-axis parabolic mirror 304 in the collection system 106. From the illumination optics module 202, the incident light beam 110 is passed through, via an optical fiber 310, the off-axis parabolic mirror 302, then through a pupil 306, then through the polarizer 210. The reflected light beam 118 is passed through pupil 308 and through the second off-axis parabolic mirror 304 to focus the reflected light beam into fiber optic 312 to the detector.

In further embodiments, in-situ optical sensor 102 of FIGS. 2 and 3, other optical components may be used, such as mirrors, prisms, lenses, spatial light modulators, digital micromirror devices, and the like, to steer the incident light beam 110 and the reflected light beam 118. The configuration and component layout of the optical sensor 102 of FIGS. 2 and 3 do not necessary need to be as shown exactly in FIGS. 2 and 3, but the light beams can be folded and steered by way of additional optical components to facilitate packaging the in-situ optical sensor into a compact packaging suitable for mounting on the wall of the plasma processing chamber 112.

FIG. 4A is an exemplary configuration to obtain a reference light beam according to one example. From the shutter 128, the incident light beam 110 proceeds further to a mirror 402 which serves the purpose of directing a percentage of the incident light beam 110 into a reference channel of the spectrometer 120. The reference light beam may be focused into the optical fiber using a lens 404.

FIG. 4B is another exemplary configuration to obtain a reference light beam according to one example. The polarizer 210 (e.g., Rochon polarizer) or a beam splitter in the path of the incident light beam 110 can be used to direct light into the reference channel of the spectrometer 120. A prism 406 may be used to focus the reference light beam into the optical fiber. In one implementation, the intensity of the reference light beam may be measured using one or more photo detectors (e.g., UV, Vis, NIR) connected to the controller 126 as discussed previously herein.

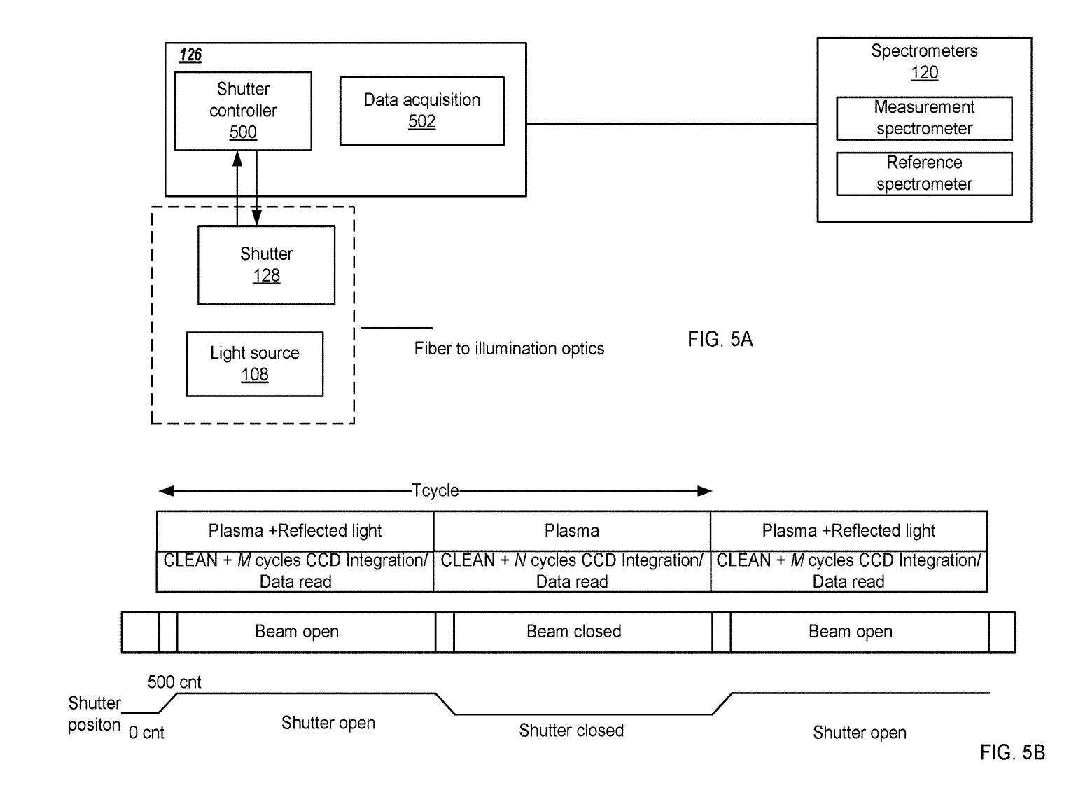

FIG. 5A is a block diagram of an optical modulation/shutter module according to one example. In one implementation, the shutter 128 may move back and forth between two positions to block or allow the incident light beam 110 into the plasma processing chamber 112. The shutter 128 may include a stepper motor. The shutter 128 with a stepper motor provides high switching speed and high repeatability and reliability. The shutter 128 may be controlled via a shutter controller 500 synchronized with the spectrometer 120. The data acquisition module 502 is connected to the reference channel of the spectrometer 120 and the measurement channel of the spectrometer 120. In one implementation, the shutter 128 may be a continuous rotation chopper.

FIG. 5B is a schematic that shows a timing diagram of the shutter 128 according to one example. The read out of the charged coupled device (CCD) has a clean cycle. When the shutter is open, the incident light beam 110 reaches the substrate 116 and thus, the measured light by the measurement channel of the spectrometer 120 is indicative of the reflected light beam 118 and the plasma emission. M cycles (i.e., CCD integration/data read) can be measured and averaged to improve signal to noise ratio (SNR). When the shutter is closed, the incident light beam 110 does not reach the substrate 116 and thus the light measured by the measurement channel of the spectrometer 120 is indicative of the plasma emission. N cycles (i.e., CCD integration/data read) can be measured and averaged to improve SNR. Thus, the controller 126 may process the collected intensities (e.g., subtract plasma intensity) in order to determine the feature dimension (e.g., thickness) from the reflected light intensity.

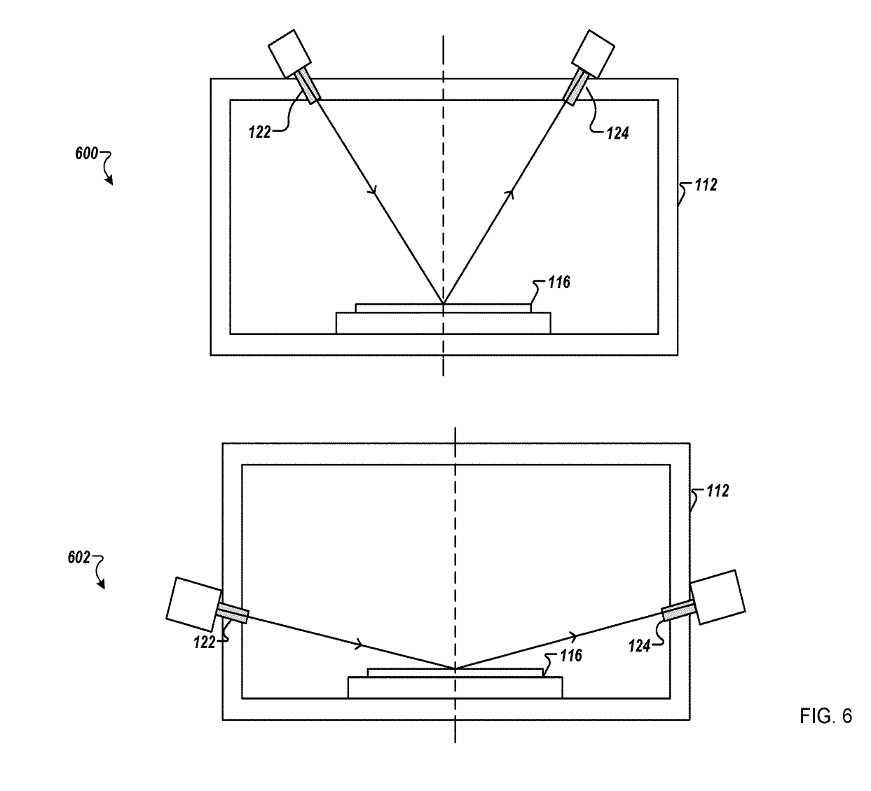

FIG. 6 is a schematic that shows exemplary configurations of the optical sensor 102. Schematic 600 shows the plasma processing chamber 112 with two optical windows 122, 124 located at the top of the plasma processing chamber 112. Schematic 602 shows a second configuration of the optical sensor 102 having the two optical windows 122, 124 on the side wall of the plasma processing chamber 112.

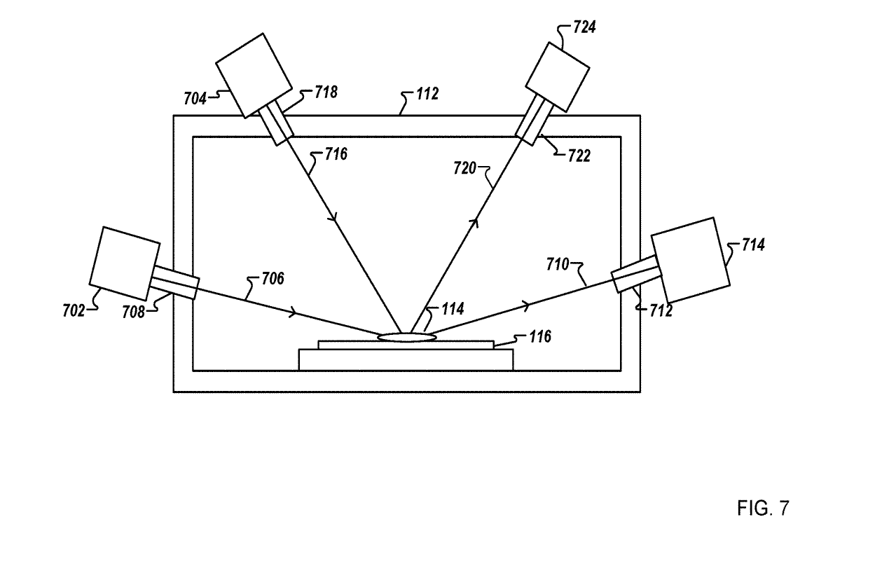

FIG. 7 is a schematic that shows a plasma processing chamber 112 equipped with an optical sensor 102 according to one example. In one embodiment, the optical sensor 102 may include multiple illumination systems configured to provide multiple incident light beams having different AOI, for example, a first illumination system 702 and a second illumination system 704. The first illumination system 702 is configured to have a first AOI and the second illumination system 704 having a second AOI. The light source 108 for the first illumination system 702 and the second illumination system 704 may be a single light source.

The incident light beam 706 having the first AOI reaches a first optical window 708 mounted on the wall of the plasma processing chamber 112 to provide access for the incident light beam 706 to the inside of the plasma processing chamber 112.

The incident light beam 706 is being reflected from the substrate 116 to form a reflected light beam 710. A second optical window 712 allows the passage of the reflected light beam 710 out of the plasma processing chamber 112 to be collected by a first collection system 714. A second incident light beam 716 at the second AOI reaches a third optical window 718 that provides access for the second incident light beam 716 to the inside of the plasma processing chamber 112. The incident light beam 716 is being reflected from the substrate 116 to form a second reflected light beam 720. A fourth optical window 722 provides access to the second reflected light beam 720 to the outside of the plasma processing chamber 112. The second reflected light beam 720 is directed by a second collection system 724 to an optical fiber coupled to the spectrometer 120.

Physical features may be determined using multiple methods from the collected spectrum. For example, physical features may be determined by referencing a library to match the detected spectrum with a pre-stored spectrum. In one implementation, direct physical regression models may be used to obtain film thickness for un-patterned wafers. Regression model may be used to measure critical dimensions (CDs) with simple patterns such as 2D lines.

In some implementations, machine learning techniques (e.g., neural network, information fuzzy network) may be used. A supervised training method trains the relationship between initial and target end-point spectrum. During the training phase of the machine learning method, the spectrum from samples is collected. The properties associated with each sample may be obtained from CD metrology tools. Then, a model is trained using the collected data and the properties of each sample.

At the real-time application stage, that trained relationship is used to predict target point from initial spectrum of each wafer. Spectra collected during etching process are compared with that predicted spectrum to detect a target end-point for each wafer.

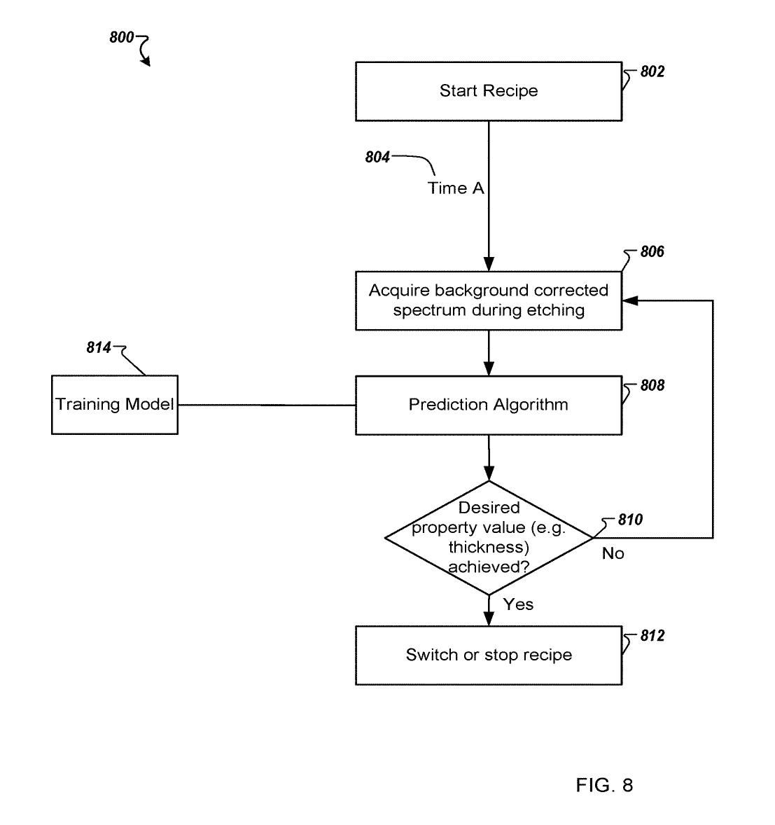

FIG. 8 is a flowchart that shows a method 800 for in-situ monitoring of an etch process according to one example. At step 802, the etching process recipe starts. After a certain time Time A≥0 sec of etching (Step 804) at step 806 a background corrected spectrum is acquired by measuring the intensity of the reflected light beam from the substrate 116 and measuring the intensity of the background light. The reflected light beam from the substrate 116 has a fixed polarization. As described previously herein, the spectrum is obtained by illuminating an area of the substrate 116 using a broadband light source. The incident light beam is modulated by the shutter 128. The reflected light beam is collected using the measurement channel of a detector.

At step 808, the prediction algorithm analyzes the acquired spectra based on a training model 814 and associates a particular property value (e.g. thickness) to that spectrum.

Then, at step 810, in response to determining that the property value has been achieved, the process proceeds to step 812. In response to determining that the property value has not been achieved, the process goes back to step 806. At step 812, the controller 126 may modify the etching process, for example, switch or stop the recipe.

The algorithms can also use periodic measurements on one or more reference substrates (calibration), such as a bare silicon wafer and/or thin-film wafers, to compensate for optical sensor or etch chamber components drifts. During calibration of the system, a beam may be reflected from a bare (i.e., unpatterned) silicon wafer or other wafer of known properties. The reflected beam is used to calibrate for any changes in the optical sensor 102, for example due to the clouding of windows (e.g., optical windows 122, 124) by products of the plasma process. The recalibration may be applied when a predetermined number of wafers have been processed in the plasma processing system 100.

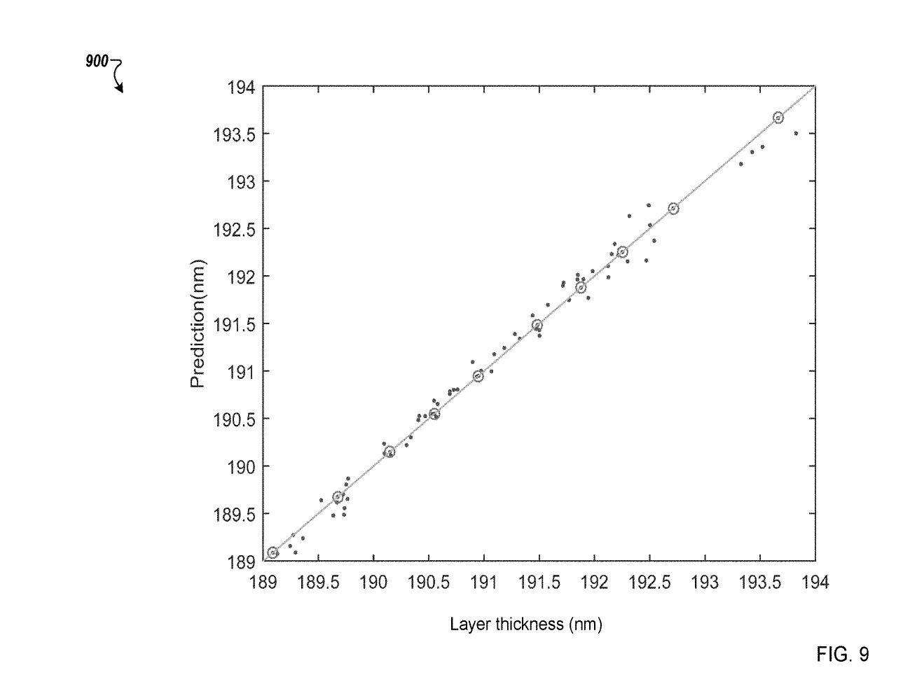

FIG. 9 is an exemplary schematic that shows exemplary results. Detection of thickness by the optical sensor 102 disclosed herein was compared to other detection methods and models. For example, a reference wafer map having M sites may be used. N sites out of the M sites that represent the range of a layer thickness in the wafer map are selected by the inventors. The selected N sites are indicated by circles in schematic 900. The linear nature of the plot shown in schematic 900 indicates a good agreement between measurements made with the optical sensor 102 described herein (vertical axis) and measurements made with another tool.

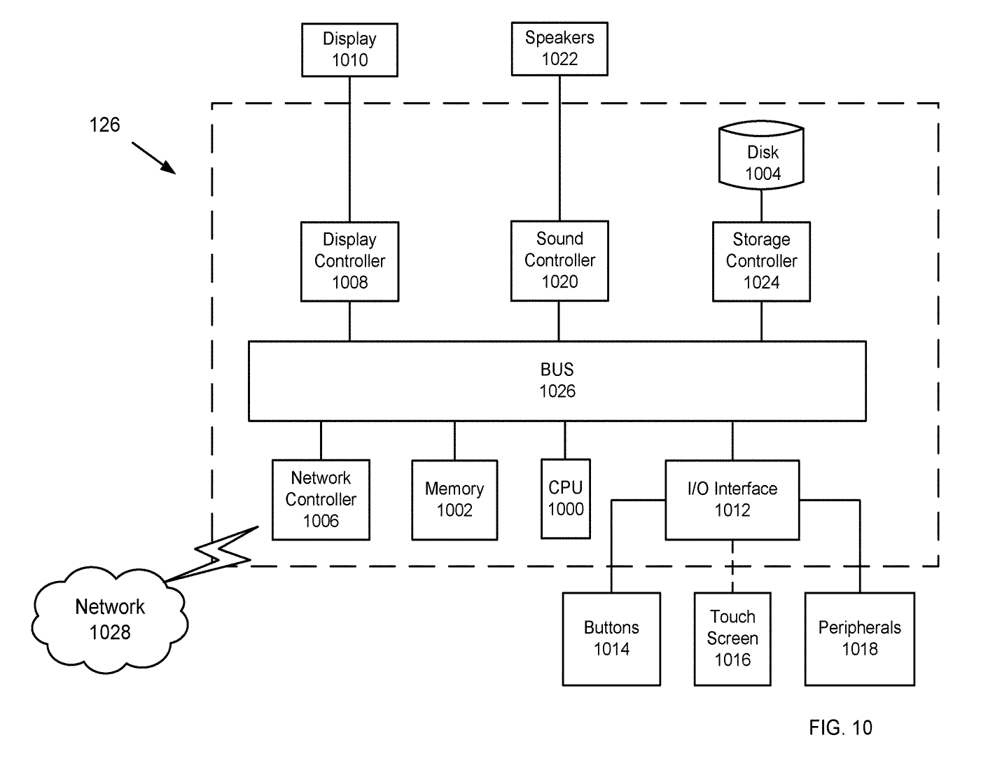

Next, a hardware description of the controller 126 according to exemplary embodiments is described with reference to FIG. 10. In FIG. 10, the controller 126 includes a CPU 1000 which performs the processes described herein. The process data and instructions may be stored in memory 1002. These processes and instructions may also be stored on a storage medium disk 1004 such as a hard drive (HDD) or portable storage medium or may be stored remotely. Further, the claimed advancements are not limited by the form of the computer-readable media on which the instructions of the inventive process are stored. For example, the instructions may be stored on CDs, DVDs, in FLASH memory, RAM, ROM, PROM, EPROM, EEPROM, hard disk or any other information processing device with which the controller 126 communicates, such as a server or computer.

Further, the claimed advancements may be provided as a utility application, background daemon, or component of an operating system, or combination thereof, executing in conjunction with CPU 1000 and an operating system such as Microsoft® Windows®, UNIX®, Oracle® Solaris, LINUX®, Apple macOS™ and other systems known to those skilled in the art.

In order to achieve the controller 126, the hardware elements may be realized by various circuitry elements, known to those skilled in the art. For example, CPU 1000 may be a Xenon or Core processor from Intel of America or an Opteron processor from AMD of America, or may be other processor types that would be recognized by one of ordinary skill in the art. Alternatively, the CPU 1000 may be implemented on an FPGA, ASIC, PLD or using discrete logic circuits, as one of ordinary skill in the art would recognize. Further, CPU 1000 may be implemented as multiple processors cooperatively working in parallel to perform the instructions of the inventive processes described above.

The controller 126 in FIG. 10 also includes a network controller 1006, such as an Intel Ethernet PRO network interface card from Intel Corporation of America, for interfacing with network 1028. As can be appreciated, the network 1028 can be a public network, such as the Internet, or a private network such as LAN or WAN network, or any combination thereof and can also include PSTN or ISDN sub-networks. The network 1028 can also be wired, such as an Ethernet network, or can be wireless such as a cellular network including EDGE, 3G and 4G wireless cellular systems. The wireless network can also be WiFi®, Bluetooth®, or any other wireless form of communication that is known.

The controller 126 further includes a display controller 1008, such as a NVIDIA® GeForce® GTX or Quadro® graphics adaptor from NVIDIA Corporation of America for interfacing with display 1010, such as a Hewlett Packard® HPL2445w LCD monitor. A general purpose I/O interface 1012 interfaces with a keyboard and/or mouse 1014 as well as a an optional touch screen panel 1016 on or separate from display 1010. General purpose I/O interface also connects to a variety of peripherals 1018 including printers and scanners, such as an OfficeJet® or DeskJet® from Hewlett Packard.

A sound controller 1020 is also provided in the controller 126, such as Sound Blaster® X-Fi Titanium® from Creative, to interface with speakers/microphone 1022 thereby providing sounds and/or music.

The general purpose storage controller 1024 connects the storage medium disk 1004 with communication bus 1026, which may be an ISA, EISA, VESA, PCI, or similar, for interconnecting all of the components of the controller 126. A description of the general features and functionality of the display 1010, keyboard and/or mouse 1014, as well as the display controller 1008, storage controller 1024, network controller 1006, sound controller 1020, and general purpose I/O interface 1012 is omitted herein for brevity as these features are known.

A system which includes the features in the foregoing description provides numerous advantages to users. In particular, the oblique incidence polarized optical system provides increased sensitivity to top layer properties monitoring. In addition, the collection of p-polarized light reflected from the substrate 116 results in better signal purity.

Obviously, numerous modifications and variations are possible in light of the above teachings. It is therefore to be understood that within the scope of the appended claims, the invention may be practiced otherwise than as specifically described herein.

Thus, the foregoing discussion discloses and describes merely exemplary embodiments of the present invention. As will be understood by those skilled in the art, the present invention may be embodied in other specific forms without departing from the spirit or essential characteristics thereof. Accordingly, the disclosure of the present invention is intended to be illustrative, but not limiting of the scope of the invention, as well as other claims. The disclosure, including any readily discernible variants of the teachings herein, defines, in part, the scope of the foregoing claim terminology such that no inventive subject matter is dedicated to the public.

1. An apparatus for in-situ etching monitoring in a plasma processing chamber, the apparatus comprising:
a continuous wave broadband light source;
an illumination system configured to illuminate an area on a substrate with an incident light beam having a fixed polarization direction, the incident light beam from the broadband light source being modulated by a shutter;
a collection system configured to
collect a reflected light beam being reflected from the illuminated area on the substrate, and
direct the reflected light beam to a detector; and
processing circuitry configured to
process the reflected light beam to suppress background light,
determine a property value from the processed light, and
control an etch process based on the determined property value.

2. The apparatus of claim 1, wherein the broadband light source is a laser driven plasma light source.

3. The apparatus of claim 1, wherein the illumination system includes a Rochon polarizer; and
the collection system includes a second Rochon polarizer configured to allow p-polarized light reflected from the substrate to reach the detector.

4. The apparatus of claim 1, wherein the illumination system and the collection system include reflective relay optics.

5. The apparatus of claim 4, wherein the reflective relay optics include off-axis parabolic mirrors.

6. The apparatus of claim 4, wherein the reflective relay optics include concave mirrors and convex mirrors.

7. The apparatus of claim 1, wherein the incident light beam has an angle of incidence between 0 to 90 degrees with respect to a normal of the substrate.

8. The apparatus of claim 7, wherein the angle of incidence is between 45 degrees to 90 degrees.

9. The apparatus of claim 8, wherein the angle of incidence is 85 degrees or 64 degrees.

10. The apparatus of claim 1, further comprising a step motor configured to move the shutter between two positions, wherein in a first position the shutter is configured to block the incident light beam from reaching the plasma processing chamber and in a second position the shutter is configured to allow the incident light beam into the plasma processing chamber.

11. The apparatus of claim 1, wherein the shutter is a chopper wheel.

12. The apparatus of claim 1, further comprising:
a second illumination system configured to illuminate the area of the substrate with a second incident light beam having a second angle of incidence, the second angle of incidence being different from the angle of incidence of the incident light beam from the illumination system, the second incident light beam being reflected from the substrate to form a second reflected light beam;
a second collection system configured to
collect the second reflected light beam, and
direct the second reflected light beam to the detector.

13. The apparatus of claim 1, further comprising:
a first optical window configured to transmit the incident light beam;
a second optical window configured to transmit the reflected light beam; and
wherein the first optical window and the second optical window are mounted on the wall of the plasma processing chamber opposite of each other.

14. The apparatus of claim 1, further comprising:
a first optical window configured to transmit the incident light beam;
a second optical window configured to transmit the reflected light beam; and
wherein the first optical window and the second optical window are mounted on a top wall of the plasma processing chamber.

15. The apparatus of claim 1, further comprising:
a reference system configured to direct a percentage of the incident light beam to a reference channel of the detector.

16. The apparatus of claim 1, wherein the detector is an ultra-broadband spectrometer.

17. A plasma processing system, the system comprising:
a plasma processing chamber; and
an oblique incidence reflectometer including
a continuous wave broadband light source,
a detector,
an illumination system configured to illuminate an area on a substrate deposited in the plasma processing chamber with an incident light beam having a fixed polarization direction, the incident light beam from the broadband light source being modulated by a shutter,
a collection system configured to
collect a reflected light beam being reflected from the illuminated area on the substrate, and
direct the reflected light beam to the detector, and
processing circuitry configured to
process the reflected light beam to suppress background light,
determine a property value from the processed light, and
control an etch process based from the determined property value.

18. The system of claim 17, wherein the broadband light source is a laser driven plasma light source.

19. A method for in-situ etching monitoring, the method comprising:
acquiring a background corrected spectrum associated with a reflected light beam during an etch process, the reflected light beam being formed from the reflection of a modulated incident light beam having a fixed polarization direction from an area of a substrate deposited in a plasma processing chamber, the incident light beam being from a broadband light source being modulated using a shutter;
determining a property value associated with the background corrected spectrum using a training model; and
controlling the etch process based on the determined property value.

20. The method of claim 19, wherein the training model is a regression model when the substrate is un-patterned and a machine learning algorithm when the substrate is patterned.
